(19) United States
(12) Patent Application Publication
(10) Pub. No.: US 2012/0138122 A1
(43) Pub. Date: Jun. 7, 2012

(54) PARABOLIC LIGHT CONCENTRATING TROUGH

(76) Inventors: John P. Whitlock, Lebanon, OR (US); Scott Lerner, Corvallis, OR (US); Stephan R. Clark, Albany, OR (US); Karl S. Weibezahn, Corvallis, OR (US)

(21) Appl. No.: 13/386,864

(22) PCT Filed: Oct. 22, 2009
(86) PCT No.: PCT/US09/61606

§ 371 Date: Feb. 23, 2012

(51) Int. Cl. H01L 31/052; F21V 7/06; B23P 11/00; G02B 5/09

(52) U.S. Cl. 136/246; 359/853; 362/297; 29/428

(57) ABSTRACT

Apparatus and methods are provided for use with photovoltaic cells, light emitting devices and the like. Reflective regions are formed on a sheet of flexible, non-metallic sheet material. The sheet material is folded to at least partially define a finished shape. Supports complete and maintain the folded condition such that one or more truncated parabolic troughs are defined. Incident light may be received and concentrated, or emitted light concentrated and projected, by way of the troughs.

### BACKGROUND

Light concentrators increase the electrical output of a given PV array at lesser cost per unit area than that of the PV cells themselves. This makes light concentrators attractive to photovoltaic designers and consumers.

However, known light concentrator technology is of sufficient cost and manufacturing complexity that improvements in this area are still desirable. It is also desirable to apply advances in this area to other technical endeavors. The present teachings address the foregoing concerns.

### BRIEF DESCRIPTION OF THE DRAWINGS

The present embodiments will now be described, by way of example, with reference to the accompanying drawings, in which:

FIG. 1 depicts a plan view of a processed strip according to one embodiment;

FIG. 2 depicts a plan view of a support according to one embodiment;

FIG. 3 depicts a plan view of a support according to another embodiment;

FIG. 4 depicts an isometric view of an apparatus according to one embodiment;

FIG. 5 depicts an isometric view of an apparatus according to another embodiment;

FIG. 6 depicts an elevation cross-section of an apparatus according to an embodiment;

FIG. 7 depicts an elevation cross-section of an illustrative use according to one embodiment;

FIG. 8 depicts an elevation cross-section of another illustrative use according to one embodiment;

FIG. 9 depicts a flow diagram of a method according to another embodiment.

### DETAILED DESCRIPTION

### Introduction

Means and methods are provided for use with photovoltaic cells, light emitting devices and the like. Reflective regions are formed on a flexible, non-metallic sheet material. The sheet material is folded so as to at least partially define a finished shape. Supports are joined to the sheet material to complete and maintain the folded condition such that one or more truncated parabolic troughs are defined. Incident light may be received and concentrated, or emitted light concentrated and projected, by way of the troughs.

In one embodiment, an apparatus includes a flexible non-metallic sheet material that is flexed so as to define one or more troughs. Each trough is defined by a truncated parabolic cross-section. The flexible non-metallic sheet material includes a plurality of light reflecting regions. Each light reflecting region faces into a respective one of the troughs. The apparatus also includes at least one support that is configured to maintain the flexed condition of the flexible non-metallic sheet material.

In another embodiment, a method includes forming a plurality of reflective regions on a flexible sheet material. The corresponding regions of the flexible sheet material are about planar during the forming of the reflective regions. The method also includes folding the flexible sheet material so as to define one or more troughs. Each trough is defined by a truncated parabolic cross-section. Additionally, each trough is at least partially defined by a pair of the reflective regions. The method further includes supporting the flexible sheet material so as to maintain the folded condition.

### First Illustrative Elements

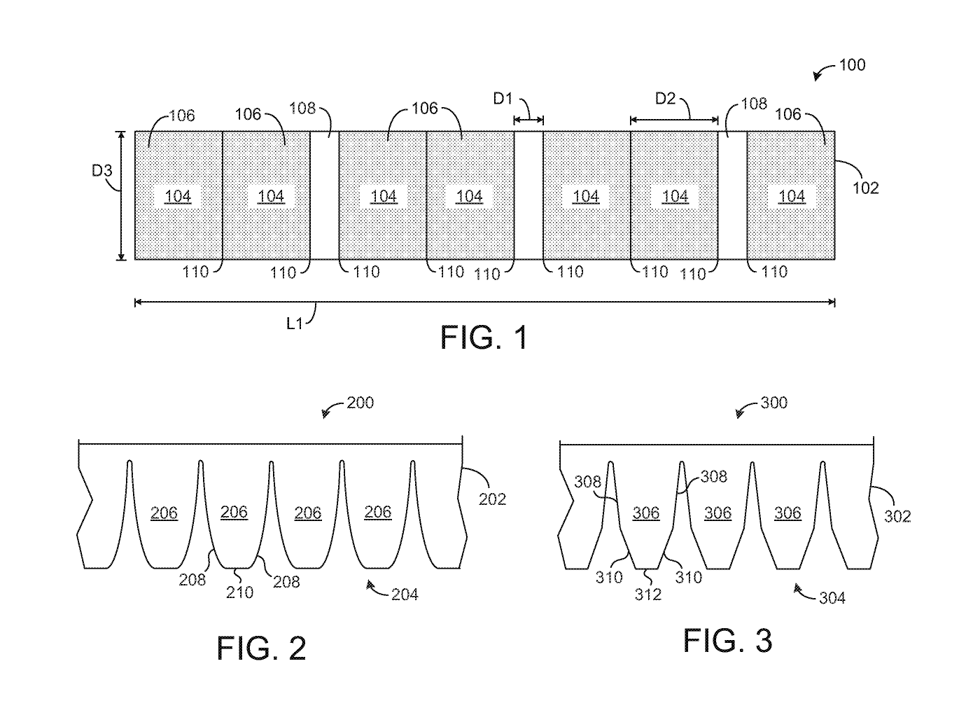

Reference is now made to FIG. 1, which depicts a plan view of a processed strip 100 of material according to the present teachings. The processed strip 100 is illustrative and non-limiting with respect to the present teachings. Thus, other embodiments can be configured and/or used in accordance with the present teachings, including respectively varying characteristics and elements.

The processed strip 100 includes a strip of sheet material 102. The sheet material 102 can be defined by any suitable flexible, transparent, non-metallic sheet material including, for non-limiting example, Mylar, polyethylene, plastic, etc. Other suitable materials or combinations of materials can also be used. In one embodiment, the sheet material 102 is, at least some of the time, in roll form and can be shipped, processed and handled as such.

The processed strip 100 also includes a plurality of light reflecting regions 104 formed thereon. The light reflecting regions 104 include a light reflecting material 106 that has been deposited, or bonded, to the sheet material 102. Non-limiting examples of such light reflecting material 106 include aluminum, silver, dielectric materials, etc. The light reflecting material 106 can be deposited by any suitable means or process such as, without limitation, physical vapor deposition (PVD), chemical vapor deposition (CVD), sputtering, plasma-enhanced chemical vapor deposition (PECVD) or by other suitable processes. In one embodiment, the light reflecting material 106 is provided as a thin metallic film and is adhered to the sheet material 102 by way of transparent cement.

The sheet material 102 also includes, or defines, a plurality of strips 108. Each of the strips 108 is defined by a portion of the sheet material 102 without ht reflecting material (e.g., 106) there on. Strip 108 may also be defined by a through aperture in the sheet material 102. As depicted, the processed strip 100 is of an illustrative length “L1”. However, it is to be understood that the processed strip 100 and characteristics thereof can be extended over any practical length of sheet material 102. Thus, the present teachings contemplate any number of processed strips 100 having any respective number of light reflecting regions 104 and strips 108. Furthermore, the particular dimensions taught hereinafter are illustrative and non-limiting in nature.

The processed strip 100 also includes a plurality of fold lines 110. The fold lines 110 can be formed by any suitable means such as, without limitation, laser ablation, mechanical cutting, diamond-tip scribing, etc. The fold lines 110 extending partially through the thickness of the sheet material 102. It is noted that the fold lines extend across a width-wise dimension “D3” of the sheet material 102 and are coincident with respective edges of the light reflecting regions 104 and the strips 108.

In one or more embodiments, some suitable fraction of the sheet material 102 is supported in a substantially flat or planar orientation during the deposition of the light reflecting material 106 into the light reflecting regions 104. In this way, the sheet material 102 can be drawn from a source roll and the light reflecting regions 104 can be formed or other processing steps performed in a continuous, batch-wise, or combined manner. Further discussion on the processing of sheet material in accordance with the present teachings is provided hereinafter. Table 1 below summarizes illustrative and non-limiting characteristics for one embodiment of processed strip 100:

TABLE 1
Processed Strip 100

| Element | Description/Notes |
|---|---|
| Sheet 102 | Mylar, 80 microns thick |
| Reflective 104 | Aluminum, 100 nm thick, 92% reflective |
| Dimension D1 | 6 millimeters |
| Dimension D2 | 25 millimeters |
| Dimension D3 | 25 millimeters |

Attention is now directed to FIG. 2, which depicts a plan view of a support 200 according to an embodiment of the present teachings. The support 200 is illustrative and non-limiting with respect to the present teachings. Thus, other supports can be configured and/or used in accordance with the present teachings. As used herein, the support 200 is also referred to as a “rib” or ‘supportive rib’ 200.

The support 200 is formed from any suitable rigid to semi-rigid sheet material 202. Non-limiting examples of such materials include plastic, metal, polyethylene, cast epoxy, polymer materials, etc. In one embodiment, the support 200 is formed from plastic sheet material having a thickness of two millimeters. Other materials or thicknesses can also be used.

The support 200 includes a periphery 204 that defines a plurality of peninsulas 206. Each peninsula 206 is defined by a truncated parabolic shape including two curvilinear side portions 208 and a linear end portion 210. The support 200 is formed so as to join and support an associated processed strip (e.g., 100) in a flexed (or folded) condition.

Attention is now directed to FIG. 3, which depicts a plan view of a support 300 according to another embodiment of the present teachings. The support 300 is illustrative and non-limiting with respect to the present teachings. Thus, other supports can be configured and/or used in accordance with the present teachings. As used herein, the support 300 is also referred to as a “rib” or “supportive rib” 300.

The support 300 is formed from any suitable rigid to semi-rigid sheet material 302. Non-limiting examples of such materials include plastic, metal, polyethylene, cast epoxy, polymer materials, etc. In one embodiment, the support 300 is formed from plastic sheet material having a thickness of two millimeters. Other materials or thicknesses can also be used.

The support 300 is defined by a periphery 304 that defines a plurality of peninsulas 306. Each peninsula 306 is defined by a step-wise tapered shape including two linear side portions 308, two linear side portions 310 and a linear end portion 312. The support 300 is formed so as to support an associated processed strip (e.g., 100) in a flexed (or folded) condition consistent with the present teachings.

### First Illustrative Embodiment

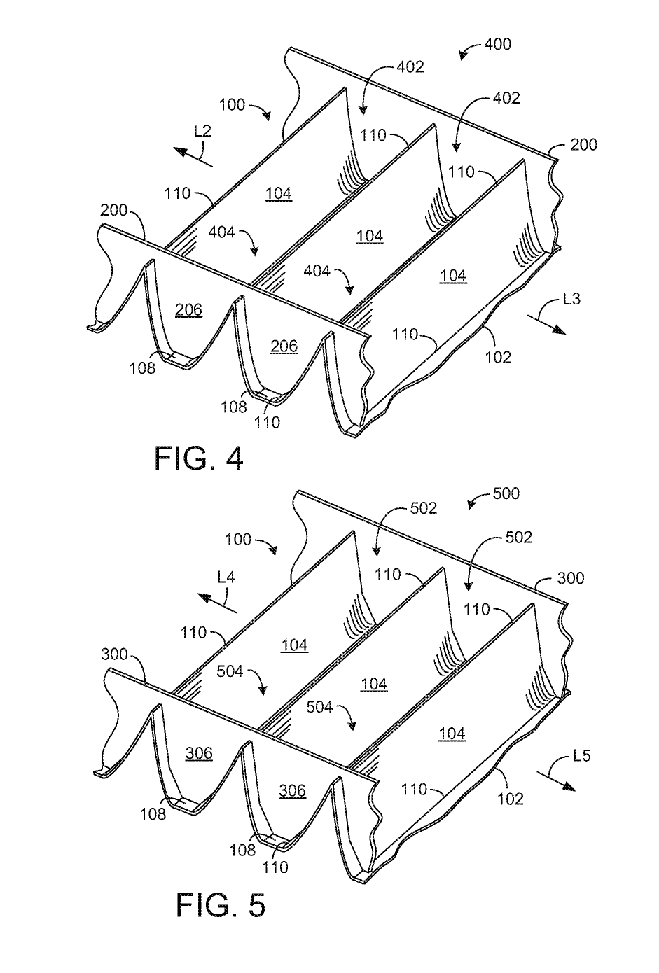

Attention is now directed to FIG. 4, which depicts an isometric view of a portion of an apparatus 400 according to the present teachings. The apparatus 400 is illustrative and non-limiting in nature. Other apparatus can be defined, configured and used in accordance with the present teachings.

The apparatus 400 includes the processed strip 100 described above. The processed strip 100 has been flexed, or folded, along respective fold lines 110 so as to define a plurality of parallel troughs 402. Each of the troughs 402 is defined by a truncated parabolic cross-section.

The apparatus 400 also includes a pair of supports 200 as described above. The supports 200 are bonded (or joined) to the processed strip 100 so as to complete and maintain the flexed condition thereof, thus preserving the shape of the troughs 402. Bonding of the supports 200 to the processed strip 100 can be done in any suitable way such as, without limitation, epoxy bonding, laser welding, thermal fusing, post-and-hole snap construction, etc. Other suitable bonding means can also be used.

It is noted that the truncated parabolic cross-sections of the troughs 402 corresponds to the peripheral shape of the respective peninsulas 206. Thus, the processed strip 100 can be bonded to the peninsulas 206 continuously along the contacting edge, or at some discrete number of contacting points or edge segments.

Each trough 402 is partially defined by a corresponding pair of the reflective regions 104. That is, any particular pair of reflective regions 104 defines the curved, inward facing side walls of a corresponding trough 402. Each trough 402 is further defined by a corresponding strip 108. Thus, each strip 108 defines a planar bottom region 404 for a corresponding trough 402.

The apparatus 400 is depicted as a portion or fraction of an overall entity in the interest of clarity of detail. As such, the apparatus 400 depicts two troughs 402. However, it is to be understood that the apparatus 400 can extend in either or both lengthwise directions “L2” and “L3” such that any suitable number of troughs 402 are defined.

### Second Illustrative Embodiment

Referring now to FIG. 5, which depicts an isometric view of a portion of an apparatus 500 according to the present teachings. The apparatus 500 is illustrative and non-limiting in nature. Other apparatus can be defined, configured and used in accordance with the present teachings.

The apparatus 500 includes the processed strip 100 described above. The processed strip 100 has been flexed, or folded, along respective fold lines 110 so as to define a plurality of parallel troughs 502. Each of the troughs 502 is defined by a truncated parabolic cross-section.

The apparatus 500 also includes a pair of supports 300 as described above. The supports 300 are bonded (or joined) to the processed strip 100 so as to complete and maintain the flexed condition thereof, thus preserving the shape of the troughs 502. Bonding of the supports 300 to the processed strip 100 can be done in any suitable way such as, without limitation, epoxy bonding, laser welding, thermal fusing, post-and-hole snap construction, etc. Other suitable bonding means can also be used.

It is noted that the troughs 502 retain their truncated parabolic cross-sections despite the linear-sided periphery of the peninsulas 306. Thus, the processed strip 100 is in contact with the peninsulas 306 only at those points or edge segments consistent with maintaining the truncated parabolic form of the troughs 502.

Each trough 502 is partially defined by a corresponding pair of the reflective regions 104. That is, any particular pair of reflective regions 104 defines the curved, inward facing side walls of a corresponding trough 502. Each trough 502 is further defined by a corresponding strip 108. Thus, each strip 108 defines a planar bottom region 504 for a corresponding trough 502.

The apparatus 500 is depicted as a portion or fraction of an overall entity in the interest of clarity of detail. As such, the apparatus 500 depicts two troughs 502. However, it is to be understood that the apparatus 500 can extend in either or both lengthwise directions “L4” and “L5” such that any suitable number of troughs 502 are defined.

### Illustrative Details

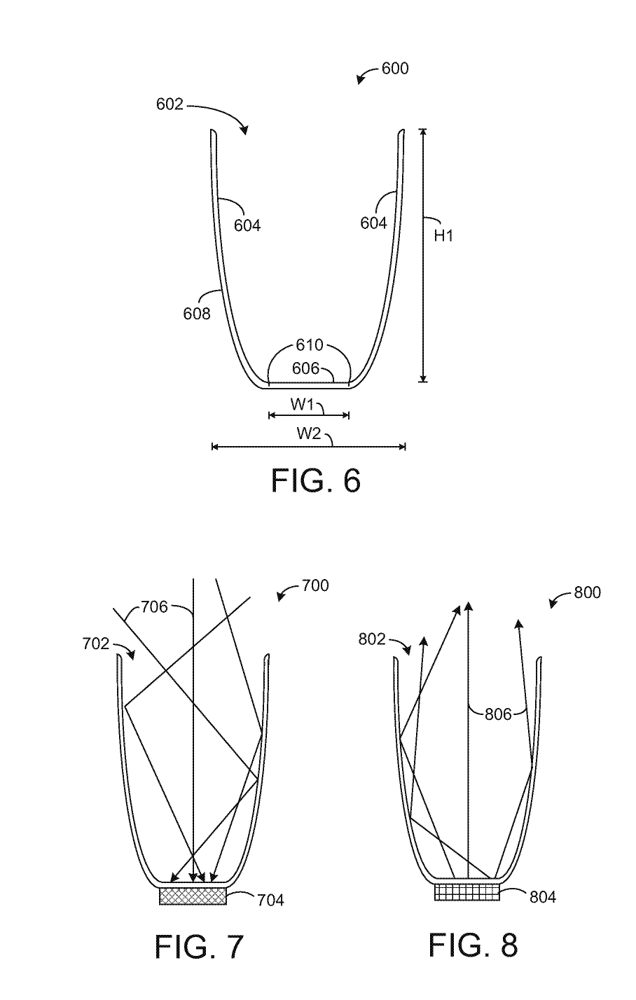

Attention is now directed to FIG. 6, which depicts an elevation cross-section of a device 600 according to the present teachings. The device 600 is illustrative and non-limiting with respect to the present teachings. Thus, other devices are also contemplated within the scope of the present teachings.

The device 600 includes a trough 602 defined by a pair of reflective side walls 604 and a transparent, planar bottom portion 606. The trough 602 is defined by a truncated parabolic cross-sectional shape. The reflective side walls 604 include reflective regions (e.g., 104) formed on a non-metallic sheet material 608. The side walls 604 are flexed, or folded, along fold lines 610 defined in the sheet material 608. While not shown in FIG. 6, it is assumed that a suitable support (e.g., 200) has been bonded to the sheet material 608 such the characteristic parabolic shape of the trough 602 is maintained.

The truncated parabolic cross-section of the trough 602 is characterized by dimensions “H1”, “W1” and “W2” as depicted. Illustrative and non-limiting dimensions for one embodiment of the device 600 are summarized below in Table 2:

TABLE 2
Device 600

| Element | Description/Notes |
|---|---|
| Dimension H1 | 24 millimeters |
| Dimension W1 | 6 millimeters |
| Dimension W2 | 18 millimeters |
| Sheet 608 | Mylar, 80 microns thick |

### Third Illustrative Embodiment

Reference is now made to FIG. 7, which depicts an elevation section view of a device 700 according to another embodiment of the present teachings. The device 700 is illustrative and non-limiting with respect to the present teachings. Thus, other devices are also contemplated within the scope of the present teachings.

The device 700 includes a truncated parabolic trough 702 in accordance with the present teachings as described above. The device 700 also includes a photovoltaic (PV) cell 704. The PV cell 704 is contactingly supported beneath a transparent bottom portion of the trough 702. As such, incident light 706 entering the trough 702 is concentrated by reflection onto the PV cell 704. In this way, incident light rays (i.e., sunlight, etc.) 706 are directed onto the PV cell 704 that would otherwise be missed.

In one embodiment, the trough 702 is configured such that a light concentration ratio of ten is achieved. Put another way, light capture by the PV cell 704 is ten times greater than that achieved without the trough 702. In turn, the PV cell 704 provides proportionally increase electrical production. Other embodiments having other light concentration ratios can also be configured and used. In another embodiment (not shown), the PV cell (e.g., 704) is located within the trough 702 rather than beneath it.

It is to be understood that the device 700 is depicted with a single PV cell 704. However, one having ordinary skill in the electrical arts will appreciate that light concentrating troughs (e.g., 402, 502, etc.) can be configured to accommodate any practical number of photovoltaic cells. Furthermore, multiple such light concentrating troughs can be arranged as an array of any practical area. Thus, entire photovoltaic systems can be designed that take advantage of the light concentrating devices of the present teachings.

### Fourth Illustrative Embodiment

Attention is directed to FIG. 8, which depicts an elevation section view of a device 800 according to another embodiment of the present teachings. The device 800 is illustrative and non-limiting with respect to the present teachings. Thus, other devices are also contemplated within the scope of the present teachings.

The device 800 includes a truncated parabolic trough 802 in accordance with the present teachings as described above. The device 800 also includes a light emitting device 804. In one embodiment, the light emitting device is defined by one or more light-emitting diodes (LEDs). Other light emitters can also be used. The light emitting device 804 is contactingly supported beneath a transparent bottom portion of the trough 802. As such, light rays 806 emitted by the device 804 are concentrated by reflection and projected out of the trough 802. A generally coherent, directed beam of light is thus generated.

It is to be understood that the device 800 is depicted with a single light emitter 804. However, one having ordinary skill in the electrical arts will appreciate that light concentrating troughs (e.g., 402, 502, etc.) can be configured to accommodate any practical number of light emitters (e.g., LEDs, incandescent lamps, fluorescent devices, etc.). Furthermore, multiple such light concentrating troughs can be arranged as an array of any practical area. Thus, various light beaming apparatus can be designed in accordance with the present teachings.

### First Illustrative Method

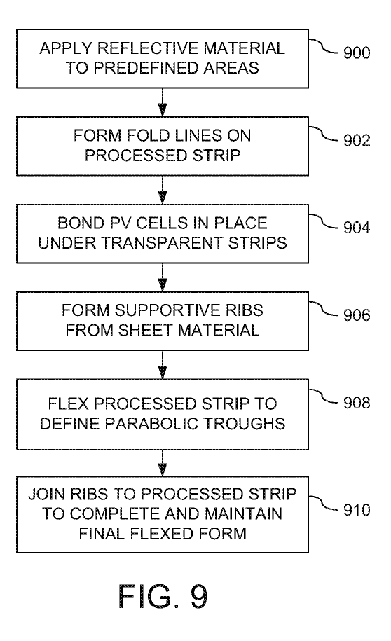

FIG. 9 is a flow diagram depicting a method according to one embodiment of the present teachings. The method of FIG. 9 includes particular operations and order of execution. However, other methods including other operations, omitting one or more of the depicted operations, and/or proceeding in other orders of execution can also be used according to the present teachings. Thus, the method of FIG. 9 is illustrative and non-limiting in nature. Illustrative reference is also made to FIGS. 1, 3, 5 and 7 in the interest of understanding the method of FIG. 9.

At 900, reflective material is applied to predefined areas of a flexible, non-metallic sheet material. For purpose of non-limiting illustration, it is assumed that aluminum is applied to a strip of plastic sheet material 102 so as to form a plurality of reflective regions 104. Such formation can be performed by way of deposition, adhesion of pre-formed pieces of reflective material, etc. From this point forward in the method, the sheet material is referred to as a processed strip.

At 902, plural fold lines are formed in the processed strip. For purposes of the ongoing illustration, it is assumed that fold lines 110 are formed across the processed strip 102 by way of laser ablation, mechanical cutting, etc. The fold lines extend partially, but not completely, through the sheet material. In this way, boundaries between discrete light reflecting regions 104 and (transparent) strips 108 are defined.

At 904, one or more photovoltaic cells are bonded beneath a transparent area (or though aperture) of the processed strip. For purposes of the ongoing example, plural PV cells 704 are bonded beneath transparent (or open) strips 108 of the sheet material 102. Such bonding can be performed using optical grade epoxy, transparent cement, etc.

At 906, supportive ribs are formed from a sheet material. For purposes of the ongoing example, it is assumed that a rigid plastic material of about 2 millimeters thickness is used to form a plurality of supports 300. Each of the supports 300 is formed to define a plurality of peninsulas 306. In one or more embodiments, the supportive ribs are processed to define light reflective regions there on.

At 908, the processed strip is flexed so as to define one or more truncated parabolic troughs. For purposes of the ongoing example, it is assumed that the processed strip 102 is flexed so that numerous parabolic troughs 502 are a least partially defined. Each of the troughs 502 includes a pair of the light reflecting regions 104 and a transparent bottom strip 108 bearing the PV cells 704.

At 910, the supportive ribs are joined to the processed strip so as to complete and maintain the final flexed form. For purposes of the ongoing example, it is assumed that the support ribs 300, formed at step 906 above, are joined to the processed strip 102 such that an apparatus 500 is defined. The ribs 300 can be joined to the processed strip 102 by way of thermal bonding, epoxy, laser welding, mechanical fasteners or other suitable means. In this way, numerous light concentrating, parabolic troughs are formed and configured to increase the electrical generating output of the PV cells 704 bonded thereto.

In accordance with the present teachings, and without limitation, light concentrating troughs having a truncated parabolic form are fabricated and used. Flexible, non-metallic sheet material is processed so as to form light-reflective regions thereon. These individual regions are typically, but not necessarily, rectangular in their original shape. Such formation can be performed while the sheet material, or a portion thereof, is supported in a generally planar condition during reflective material deposition. However, this aspect can be altered as desired in accordance with the light reflective region formation process.

Additionally, areas referred to herein as strips are defined along the sheet material. These strips are typically, but not necessary, transparent in nature and coincide with the location of PV cells or light emitters to be used with the light concentrating troughs. The sheet material can be of any practical length and width, having any practical number of reflective regions and strips defined thereon. Fold lines can be scribed, ablated or otherwise formed across the flexible material in correspondence to the final shape to be achieved.

The processed sheet material is then flexed or folded along the fold lines toward a final shape. One or more support pieces, or ribs, are then joined to the sheet material so as to complete and maintain the final shape wherein one or more parallel, truncated parabolic troughs are defined. Each trough includes two of the light reflective regions defining respective inward-facing sidewalls and one of the strips defining a generally planar bottom. The two light reflective regions of each trough are flexed and supported in accordance with the final truncated parabolic shape. Photovoltaic cells or light emitting devices can advantageously exploit the light concentrating characteristics of the resulting construct.

The flexible, non-metallic sheet material can be in roll form prior to processing and at other suitable times leading up to the final shape of the light concentrating device. In this way, the light concentrating devices of the present teachings can leverage the economics of readily available plastics, Mylar, or other similar non-metallic materials. Furthermore, the ribs or other support pieces can be constructed of plastic, cast epoxy or other economically available materials. Plastic construction is also advantageous from the perspective of water-resistance and a lack of rust or other types of corrosion. One having ordinary skill in the plastic fabrication arts can appreciate that material selection is important so as to avoid undesirable effects from water absorption or other factors relevant to applications of the present teachings.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. An apparatus, comprising:
a flexible non-metallic sheet material flexed so as to define one or more troughs, each trough defined by a truncated parabolic cross-section, the flexible non-metallic sheet material including a plurality of light reflecting regions, each light reflecting region facing into a respective one of the troughs; and
at least one support configured to maintain the flexed condition of the flexible non-metallic sheet material.

2. The apparatus according to claim 1, the flexible non-metallic sheet material supporting at least one other material configured to define the plurality of light reflecting regions.

3. The apparatus according to claim 2, the at least one other material including at least aluminum, silver or a dielectric material.

4. The apparatus according to claim 2, each of the plurality of light reflecting regions defined by a reflectivity of at least ninety-two percent.

5. The apparatus according to claim 1, each of the troughs further defined by an aperture and a planar bottom disposed opposite of the aperture.

6. The apparatus according to claim 1, each of the troughs further defined by a planar bottom, each trough configured to concentrate incident light onto the planar bottom.

7. The apparatus according to claim 1 further comprising one or more photovoltaic cells configured to receive concentrated light by way of the one or more troughs.

8. The apparatus according to claim 1 further comprising one or more light emitters configured to project concentrated light by way of the one or more troughs.

9. The apparatus according to claim 1, the flexible non-metallic sheet material including at least one of plastic, Mylar or a polymeric material.

10. The apparatus according to claim 1, the at least one support including at least one of plastic, cast epoxy, metal, polyethylene or a polymeric material.

11. The apparatus according to claim 1, the at least one support formed from a sheet material and defined by a peripheral shape corresponding to the truncated parabolic cross-section of each trough.

12. A method, comprising:
forming a plurality of reflective regions on a flexible sheet material, the corresponding regions of the flexible sheet material being about planar during the forming;
folding the flexible sheet material so as to define one or more troughs, each trough defined by a truncated parabolic cross-section, each trough at least partially defined by a pair of the plurality of reflective regions; and
supporting the flexible sheet material so as to maintain the folded condition.

13. The method according to claim 12 further comprising:
forming one or more supports; and
joining the flexible sheet material to the one or more supports so as to maintain the folded condition of the flexible sheet material.

14. The method according to claim 12 further comprising forming fold lines in the flexible sheet material prior to the folding.

15. The method according to claim 12 further comprising supporting the flexible sheet material by way of one or more mechanical fasteners so as to maintain the folded condition.

16. The method according to can 12 further comprising supporting one or more photovoltaic cells by way of the flexible sheet material, the one or more photovoltaic cells configured to receive concentrated light by way of the one or more troughs after the folding the flexible sheet material.

17. The method according to claim 12 further comprising supporting one or more light emitting devices by way of the flexible sheet material, the one or more light emitting devices configured to project concentrated light by way the one or more troughs after the folding the flexible sheet material.
